(19) United States
(12) Patent Application Publication
(10) Pub. No.: US 2026/0230001 A1
(43) Pub. Date: Aug. 6, 2026

(54) HOUSING FOR PROGRAMMABLE POWER ARRAY ENERGY ROUTER

(71) Applicant: VIRGINIA TECH INTELLECTUAL PROPERTIES, INC., Blacksburg, VA (US)

(72) Inventors: Richard Zhang, Great Falls, VA (US); Yi-Hsun Hsieh, Blacksburg, VA (US); Shivani Harikesh Nair, Arlington, VA (US); William Chong, Ashburn, VA (US)

(21) Appl. No.: 19/531,306

(22) Filed: Feb. 5, 2026

Related U.S. Application Data
(60) Provisional application No. 63/754,074, filed on Feb. 5, 2025.
(60) Provisional application No. 63/782,054, filed on Apr. 2, 2025.

(51) Int. Cl. H02M 7/00; H02M 7/219; H05K 7/02; H05K 7/14; H05K 7/20

(52) U.S. Cl. CPC H02M 7/003; H02M 7/219; H05K 7/023; H05K 7/1432; H05K 7/20927

(57) ABSTRACT

An example field programmable power array (FPPA) housing includes a first housing shell layer, where the first housing shell layer includes a first upper direct current (DC)-side cavity, a second upper DC-side cavity, an upper alternating current (AC)-side cavity between the first upper DC-side cavity and the second upper DC-side cavity, and an upper magnetic core cavity. The FPPA housing also includes a second housing shell layer, where the second housing shell layer includes a first lower DC-side cavity, a second lower DC-side cavity, a lower AC-side cavity between the first lower DC-side cavity and the second lower DC-side cavity, and a lower magnetic core cavity.

### CROSS-REFERENCE TO RELATED APPLICATIONS

This application claims the benefit of and priority to U.S. Provisional Patent Application No. 63/754,074, filed Feb. 5, 2025, and U.S. Provisional Patent Application No. 63/782,054, filed Apr. 2, 2025, the entire contents of which are hereby incorporated herein by reference. This application is also related to Patent Cooperation Treaty (PCT) Application No. PCT/US26/13655, filed Feb. 3, 2026, the entire content of which is hereby incorporated herein by reference. This application is also related to U.S. Non-Provisional Patent Application (Attorney Docket No. 222204-1665), filed Feb. 5, 2026, and titled “PROGRAMMABLE POWER ARRAY ENERGY ROUTER,” the entire content of which is hereby incorporated herein by reference.

### BACKGROUND

Many electronic devices and systems rely upon power at a well-regulated, constant, and well-defined voltage for proper operation. In that context, power conversion devices and systems are relied upon to convert electric power or energy from one form to another. A power converter is an electrical or electro-mechanical device or system for converting electric power or energy from one form to another. As examples, power converters can convert alternating current (AC) power into direct current (DC) power, convert DC power to AC power, provide a DC to DC conversion, provide an AC to AC conversion, change or vary the characteristics (e.g., the voltage rating, current rating, frequency, etc.) of power, or offer other forms of power conversion. A power converter can be as simple as a transformer, but many power converters have more complicated designs and are tailored for a variety of applications and operating specifications.

### BRIEF DESCRIPTION OF THE DRAWINGS

Many aspects of the present disclosure can be better understood with reference to the following drawings. The components in the drawings are not necessarily to scale, with emphasis instead being placed upon clearly illustrating the principles of the disclosure. Moreover, in the drawings, like reference numerals designate corresponding parts throughout the several views.

FIG. 1 depicts an example high voltage direct current (HVDC) converter station 1000 according to various embodiments of the present disclosure.

FIG. 2 depicts a schematic of an example field programmable power array (FPPA) cell according to various embodiments of the present disclosure.

FIG. 3 depicts a schematic of an example multi-phase FPPA system for enabling bidirectional power flow according to various embodiments of the present disclosure.

FIG. 4 depicts a switch interconnect fabric of the multi-phase FPPA system shown in FIG. 3, interconnecting AC-side subcells and DC-side subcells among multiple FPPA cells to each other, according to various embodiments of the present disclosure.

FIG. 5A depicts an FPPA housing according to various embodiments of the present disclosure.

FIG. 5B depicts an exploded view of the FPPA housing shown in FIG. 5A with an interior of a lower housing shell layer exposed according to various embodiments of the present disclosure.

FIG. 5C depicts the FPPA housing shown in FIG. 5B flipped upside down to show an interior of an upper housing layer according to various embodiments of the present disclosure.

FIG. 5D depicts an exploded view of the FPPA housing shown in FIG. 5A with subcells positioned therein according to various embodiments of the present disclosure.

FIG. 6 depicts a magnetic core with insulated magnetic energy couplers (IMECs) according to various embodiments of the present disclosure.

FIG. 7A depicts an example FPPA housing for an FPPA module according to various embodiments of the present disclosure.

FIG. 7B depicts an exploded view of the FPPA housing shown in FIG. 7A according to various embodiments of the present disclosure.

### DETAILED DESCRIPTION

A high voltage direct current (HVDC) converter station is a terminal facility that converts electrical power between alternating current (AC) and direct current (DC) so that electricity can be transmitted over HVDC transmission lines or cables and then converted back to AC at the receiving end. State-of-the-art (SOTA) or some HVDC converter stations rely on modular multi-level converters (MMCs) for enabling DC transmission networks, interconnecting AC and DC grids, integrating renewable energy, and isolating grid disturbances. MMC converters rely on low frequency or line frequency transformers, which can impose large system size and weight with additional transportation and installation constraints. MMC converters also use arm inductors to limit circulating currents, and help to protect the converter during transients and faults. These arm inductors can be heavy, bulky, and expensive and cause power losses, reduced converter efficiency, and generation of extra heat that must be dissipated.

HVDC systems can be better suited than AC systems for transmitting high power levels over longer distances. With suitable components and hardware, HVDC systems can provide significantly greater power delivery at higher efficiency and density compared to AC systems. Although HVDC converter stations can initially cost more than AC substations with transformers, after a distance threshold, the total cost of HVDC systems may be lower than the total cost of AC systems due to lower cost of DC transmission lines than AC transmission lines. HVDC systems can provide reduced transmission losses, eliminate reactive power flow, and offer enhanced controllability of power transfer, especially for long-distance overhead and offshore transmission with submarine cable involving wind farms, offshore AC substations, offshore HVDC converter stations, and the like.

Some HVDC converter stations rely on single-input single-output (SISO) converters, such as MMC converters, which require more advanced protection and control for use in multi-terminal (MT) HVDC systems. Multi-terminal and/or meshed DC grids with SISO HVDC converters can increase cost, control complexity, protection complexity, and points of failure, while also reducing efficiency.

These HVDC converter stations also rely on valve module/submodule (VSM) capacitors, where capacitor size is driven by the single-phase ripple power handled, often leading to bulky designs that can exceed 60 percent of VSM volume. Additionally, some HVDC converter stations rely on inefficient insulation means for valves, such as by using air insulation from ground, thereby significantly increasing space requirements in various dimensions.

In the context outlined above, multi-input multi-output (MIMO) converters for HVDC systems are disclosed according to various embodiments. MIMO converters have not been deployed in HVDC systems due to complex control requirements and other technical challenges, and the embodiments disclosed in the present disclosure offer advancements in technology to help realize such concepts. MIMO converters for HVDC systems are realized in various ways, such as by implementing modular field programmable power array (FPPA) systems which can be controlled for fault-tolerant operation through bypass mechanisms at the cell and VSM levels and dynamic reconfiguration and programmability for power flow rerouting among AC and DC ports.

The FPPA systems of the embodiments are single-stage power converters with high-frequency isolation and designed to enable a multi-port energy router for the creation of multi-terminal DC macro grids and seamless interconnection with a bulk AC grid. A basic building block is referred to herein as an FPPA cell (also referred to herein as “cell” for short), which is a multi-port single-stage direct AC/DC/DC or AC/AC/DC power converter with high-frequency galvanic isolation that has the capability to couple at least one AC port and at least one DC port. The energy flows among the three ports can be magnetically coupled through a high-frequency transformer that includes an insulated magnetic energy coupler (IMEC). The IMEC enables a modular and ultra-high-power-density solution with uniformly distributed voltage stresses for building blocks at the AC and DC ports.

An FPPA cell may be implemented as a submodule, which can be stacked to form a module. A submodule may be encapsulated in bulk ceramic housing that provides excellent electrical insulation barriers and thermal conductive paths. A water jacket with a highly efficient milli-channel water cooling design can be embedded inside the ceramic housing to remove the heat generated from power losses. High voltage insulation barriers between the AC and DC ports are achieved through high dielectric strength polyimide layers in IMEC.

Compared with conventional MMC-based HVDC converters, the FPPA-based multi-port HVDC converter or energy router of the embodiments can achieve an ultra-high-power density in footprint and volume as the result of replacing line-frequency transformers with high-frequency transformers, eliminating bulky single-phase capacitors in each VSM, eliminating arm inductors, and replacing air insulation with high-dielectric strength polyimide layers and bulk ceramic housing between FPPA cells, VSMs, VMs, and/or valves.

According to one example, a modular field programmable power array (FPPA) system includes an FPPA cell including an alternating current (AC) port, a first (direct current) DC port, and a second DC port. The FPPA cell includes a transformer, an AC-side subcell coupled between the AC port and the transformer, a first DC-side subcell coupled between the first DC port and the transformer, and a second DC-side subcell coupled between the second DC port and the transformer. The FPPA system further includes an FPPA controller configured to control interconnections of the AC-side subcell, the first DC-side subcell, and the second DC-side subcell of the FPPA cell with a second FPPA cell.

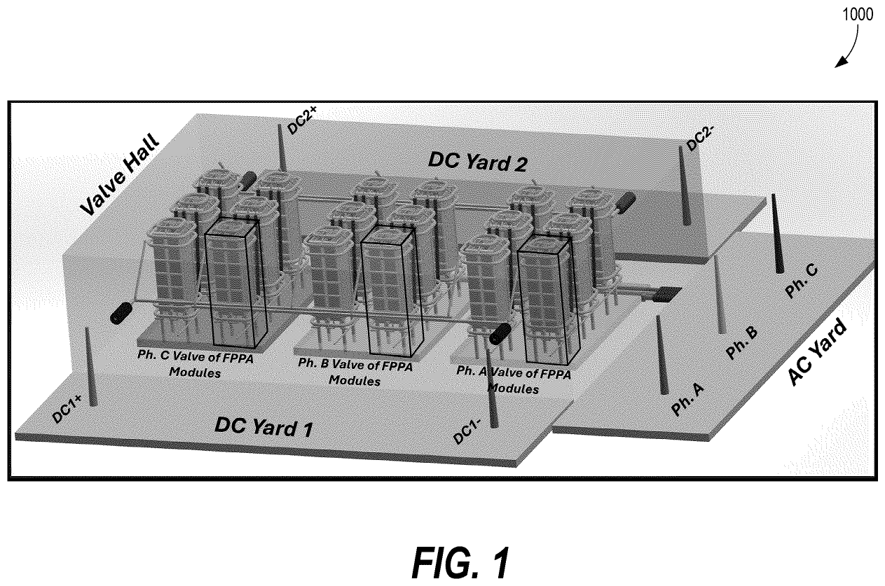

Referring now to the drawings, FIG. 1 depicts an example HVDC converter station 1000 according to various embodiments. The HVDC converter station 1000 is not exhaustively illustrated, meaning that one or more components not shown can be relied upon in some cases. Alternatively, one or more components can be omitted in practice although shown. The HVDC converter station 1000 includes an AC yard and two DC yards (e.g., DC yard 1 and DC yard 2). The HVDC converter station 1000 can interface with a three-phase AC system (e.g., bulk AC grid) through the AC yard, as indicated by Phase A, Phase B, and Phase C. For example, the HVDC converter station 1000 can include three phase legs for interfacing with the three-phase AC system. Although a three-phase AC system is shown, the HVDC converter station 1000 is not limited thereto and can interface with AC systems greater than or less than three phases. For example, the HVDC converter station 1000 can interface with a single-phase AC system via a single phase leg.

The HVDC converter station 1000 can interface with DC grids via the DC yards. In one example, the HVDC converter station 1000 can support approximately ±525 kV DC at ports of each DC yard. The HVDC converter station 1000 can be configured as a multi-port HVDC converter or energy router on HV DC grids and can be created with FPPA submodules, which can be stacked to form an FPPA module. FPPA submodules can be stacked as an FPPA module in a tower, and multiple towers can be implemented as valves in a valve hall as shown. In the example shown in FIG. 1, the HVDC converter station 1000 includes six towers in each phase leg, but the six towers are shown for illustrative purposes only.

The HVDC converter station 1000 can be used for the creation of macro-DC grids and seamless interconnection with existing bulk AC grids. The HVDC converter station 1000 is a modular HVDC converter station. For example, the HVDC converter station 1000 can include addition or removal of submodules, modules, valves, and phase legs, etc. The HVDC converter station 1000 incorporates single-stage direct AC/DC/DC power conversion topology using FPPA features, such as dynamic reconfigurability and programmability of power flow among DC and AC ports, fault-tolerant operation through bypass mechanisms at the FPPA cell and VSM levels, and advanced fault protection via current limiting and foldback functionalities at both the AC and DC ports.

The macro-DC grid's system architecture and energy flow across multiple AC and DC ports can be dynamically programmed in the field. The FPPA features of the HVDC converter station 1000 can include a control bandwidth more than 100 times greater than that of conventional MMC-based HVDC converters, enabled by silicon carbide (SiC) metal-oxide-semiconductor field-effect transistor (MOSFET) modules and high-frequency transformers within each FPPA cell, VSM, and VM according to one example. This enhanced control capability allows for the seamless implementation of advanced control, protection functions, and ancillary services for the bulk AC grid. As a result, the HVDC converter station 1000 significantly improves the operability, stability, and resilience of both the macro-DC grid and the interconnected AC counterpart.

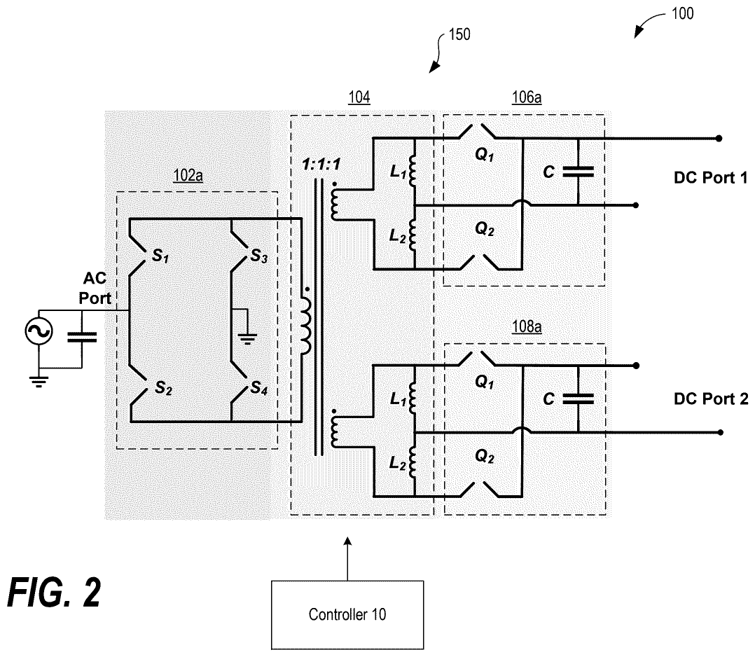

FIG. 2 depicts a schematic of an example FPPA system 100 including an FPPA cell 150 according to various embodiments. The FPPA system 100 includes an FPPA cell 150 (also referred to herein as “cell 150”), which can be configured for single-phase operation within the HVDC converter station 1000 or MVDC power converter systems and can include a single stage direct MVAC to LVDC converter topology with galvanic isolation. In some embodiments, the FPPA cell 150 can be used for MVDC applications with MVDC power converter systems. In this sense, the FPPA cell 150 is suitable for both HVDC and MVDC power converter systems and applications. The FPPA cell 150 can be configured to provide single stage direct conversion with bidirectional or in some cases unidirectional power flow. The FPPA cell 150 can be implemented as a submodule of a phase leg in the HVDC converter station 1000, and the HVDC converter station 1000 can be operable with implementation of the FPPA cell 150 for single-phase operation.

In the example shown in FIG. 2, the FPPA cell 150 includes a transformer 104, an AC-side subcell 102a coupled to a primary winding of the transformer 104 and the AC port, a DC-side subcell 106a coupled to a secondary winding of the transformer 104 and DC port 1, and a DC-side subcell 108a coupled to the secondary winding and DC port 2. Each of the DC-side subcells 106a and 108a can include bidirectional switches Q1 and Q2. Although two DC-side subcells are shown for the FPPA cell 150, the FPPA cell 150 can include only one DC-side subcell coupled to a DC port to facilitate AC/AC/DC conversion. In this sense, the FPPA cell 150 can include one or more AC-side subcells and one or more DC-side subcells for various MVDC or HVDC applications.

The AC-side subcell 102a can include bidirectional switches S1, S2, S3, and S4. A “subcell” as used herein refers to the lowest level modular building block in an FPPA cell and can include various types of switch bridges (e.g., full-bridge with bidirectional switches, half-bridge with bidirectional switches, and other types of bridge configurations) on the AC-side or various types of rectifiers (e.g., half-bridge or full-bridge rectifiers with diodes or unidirectional power switches, or bidirectional power switches) on the DC-side.

The transformer 104 includes the primary winding and the secondary winding on a magnetic core as shown, and may be operable over MF or HF bands, such as a few kHz to tens of kHz for MF and tens of kHz to MHz for HF. The magnetic core can include ferrite cores, or silicon steel, or amorphous, or nanocrystalline cores, to provide a few examples, and can be formed of various shapes such as an “E” shape, “EI” shape, “U” shape, “UI” shape, toroidal shape, and other shapes including custom core shapes using building blocks.

The FPPA cell 150 is modular. For example, the FPPA cell 150 can include additional DC-side subcells coupled with the DC-side subcell 106a and the DC port 1, and the FPPA cell 150 can include additional DC-side subcells coupled with the DC-side subcell 108a and the DC port 2. The FPPA cell 150 can include additional AC-side subcells coupled with the AC-side subcell 102a.

The total number of DC-side subcells coupled to the DC port 1 is referred to collectively as DC-side subcell(s) 106, and the total number of DC-side subcells coupled to the DC port 2 is referred to collectively as DC-side subcell(s) 108. The total number of AC-side subcells coupled to the AC port is referred to collectively as AC-side subcell(s) 102. It should be noted that the FPPA system 100 is operable with one AC-side subcell and two DC-side subcells (one DC-side subcell coupled to each DC port). In some embodiments, the FPPA system 100 can be operable with one AC-side subcell and one DC-side subcell coupled to one DC port.

To provide a few examples, the DC-side subcells 106 can include 5 DC-side subcells, 10 DC-side subcells, and other number of DC-side subcells connected in either series or parallel. The DC-side subcells 108 can include 5 DC-side subcells, 10 DC-side subcells, and other number of DC-side subcells connected in either series or parallel. The AC-side subcells 102 can include 5 AC-side subcells, 10 AC-side subcells, and other number of AC-side subcells connected in either series or parallel. The number of DC-side subcells 106 and the number of DC-side subcells 108 can be equal or different depending on application use cases of the FPPA system 100 in the HVDC converter station 1000. The number of AC-side subcells 108 and the number of DC-side subcells 106 and/or the number of DC-side subcells 108 can be equal or different.

Each of the AC-side subcell(s) 102 can include various bridge configurations such as half-bridge, full-bridge, other bridge configurations with bidirectional switches. Each of the DC-side subcell(s) 106 and the DC-side subcell(s) 108 can be embodied as a current doubler rectifier (e.g., current doubler synchronous rectifier) configured to enable the FPPA cell 150 to use or integrate a magnetizing inductance of the transformer 104 as an output filter inductor for bidirectional energy flow between the DC ports and the AC port. In some embodiments, the DC-side subcell(s) 106 and the DC-side subcell(s) 108 can be embodied as rectifiers with various bridge configurations such as half-bridge, full-bridge, or other bridge configurations, and with diode implementations or bidirectional switches. Implementation of current doubler rectifiers can provide increased power density for the FPPA system 100 while also reducing cost, especially because filter inductors, which can be bulky, expensive, and impede power density and efficiency, can be eliminated from the system.

Each of the DC-side subcell(s) 106, the DC-side subcell(s) 108, and the AC-side subcell(s) 102 can include control circuitry, bypass circuitry, and auxiliary circuitry for dynamic reconfiguration and power flow rerouting among the AC and DC ports. For example, each of the DC-side subcell(s) 106, the DC-side subcell(s) 108, and the AC-side subcell(s) 102 can be bypassed when a fault within the subcell is detected therein, based on instructions received from a FPPA controller 10 (also “controller 10” for short), enabling fault-tolerant operation of the FPPA cell 150. “Faults” as described herein may refer to electrical faults or physical faults, such as damage to subcells, submodules, and modules. Additionally, the DC-side subcells 106, the DC-side subcells 108, and the AC-side subcells 102 can be dynamically reconfigured in series or parallel connections based on instructions received from the FPPA controller 10, for achieving various power conversion objectives.

The FPPA system 100 can include the FPPA controller 10 for controlling switching operations of the AC-side subcell(s) 102 and/or the DC-side subcell(s) 106 and 108. The FPPA controller 10 can be embodied as processing circuitry, including memory, configured to control the operation of the FPPA cell 150, with or without feedback. The FPPA controller 10 can be embodied as any suitable type of controller, such as a proportional integral derivative (PID) controller, a proportional integral (PI) controller, or a multi-pole multi-zero controller, among others, to control the operations of the FPPA cell 150. The FPPA controller 10 can be realized using a combination of processing circuitry and referenced as a single controller. It should be appreciated, however, that the FPPA controller 10 can be realized using a number of controllers, control circuits, drivers, and related circuitry, operating with or without feedback.

The FPPA controller 10 can include software or hardware control and can be configured to execute various control algorithms for control of the FPPA cell 150. For one control level, the FPPA controller 10 can be configured to generate switching control signals (e.g., pulse-width modulation (PWM)) for switches of the AC-side subcell(s) 102 and/or the DC-side subcell(s) 106 and 108 for enabling bidirectional power flow between the AC and DC ports and for enabling bypass mechanisms at the cell level. Implementation of bypass mechanisms at the cell level can enable maximum fault tolerance at the lowest modular level. The bypass mechanisms include power semiconductor bypass at the AC ports for the AC-side subcell(s) 102 and the DC ports for the DC-side subcell(s) 106 and 108.

For example, at the AC port, SiC bidirectional MOSFETs (e.g., in a full-bridge or half-bridge) for the AC-side subcell(s) 102 can handle bypassing via the bypass circuitry which may be included with each of the AC-side subcell(s) 102 in response to detection of faults by the FPPA controller 10. At each of the DC ports, SiC MOSFET synchronous rectifiers may handle bypassing via the bypass circuitry which may be included with each of the DC-side subcell(s) 106 and 108 in response to detection of faults by the FPPA controller 10. The high switching frequency of SiC MOSFETs, intelligent local gate drivers for fault detection and protection, and high-speed serial link control communication system can enable rapid FPPA VSM bypass protection.

The FPPA controller 10 can be configured to implement mechanical bypass for the DC-side subcell(s) 106, the DC-side subcell(s) 108, and the AC-side subcell(s) 102 of the FPPA cell 150. Once the FPPA controller 10 confirms a fault, a secondary bypass mechanism using mechanical contacts can be engaged, after faulty subcell has been isolated and the energy stored in the faulty DC subcell has been dissipated, for added protection.

In an example embodiment, SiC MOSFETs with embedded schottky barrier diodes (SBDs) on the same chip can be utilized for the switches of the DC-side subcell(s) 106, the DC-side subcell(s) 108, and the AC-side subcell(s) 102, which can reduce switching losses by approximately 59% compared to conventional high voltage SiC MOSFETs with co-packaged separate SBDs. Implementation of the SBDs can enable a high PWM switching frequency, yet maintain substantially low switching losses. The DC filter inductance can be realized, with integrated magnetic design, by the magnetizing inductance of the transformer 104.

For a second control level, the FPPA controller 10 can be configured to implement circuit control by sending a signal or a pulse to the FPPA cell 150 for achieving various power conversion objectives. For example, the FPPA controller 10 can be configured to direct each of the DC-side subcell(s) 106, the DC-side subcell(s) 108, and the AC-side subcell(s) 102 via the control circuitries or bypass circuitries included in each of the DC-side subcell(s) 106, the DC-side subcell(s) 108, and the AC-side subcell(s) 102, to generate or regulate a specific DC voltage at a DC port, generate or regulate a specific AC voltage at an AC port, and/or shape AC input current and/or AC output current. The controller 10 can direct fault-tolerant operation for the FPPA system 100 and the FPPA cell and VSM levels and enable advanced fault protection via current limiting and foldback functionalities at both the AC and DC ports.

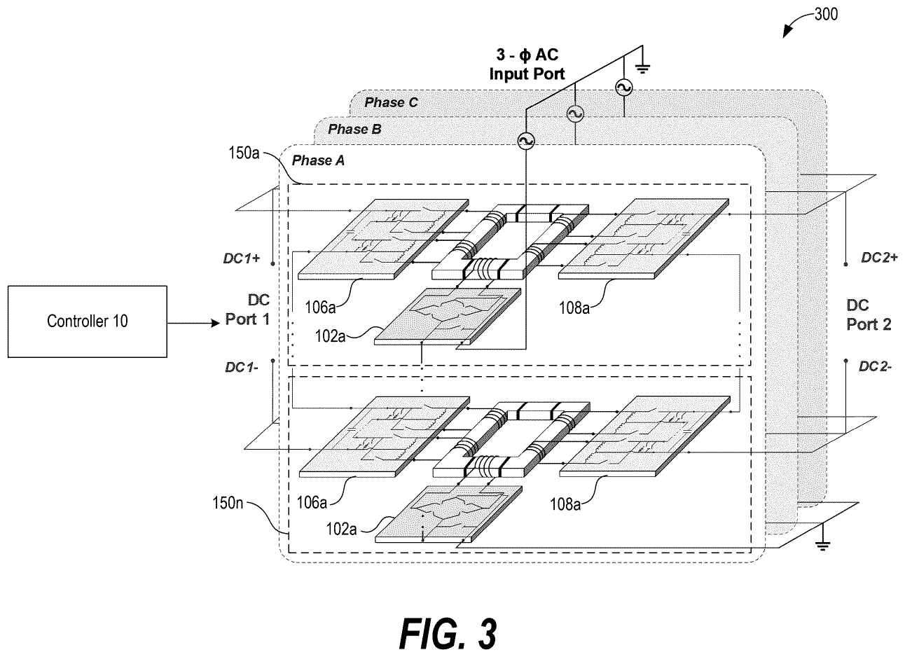

The FPPA cell 150 can serve as a modular building block for various FPPA systems such as the FPPA system 100A. The FPPA cell 150 can be a single-stage direct AC/DC/DC power converter combined with advanced power electronics control, insulated design, thermal management, and packaging technologies, and presents alternative solutions compared to conventional MMC-based HVDC converters. Incorporation of the FPPA cell 150 can provide power density with orders of magnitude of improvement over existing solutions, exceptional efficiency, high reliability and lifespan (through N+M internal redundancy (where “N” denotes a minimum number of subcells needed to operate and “M” denotes the number of redundant subcells added) and fast bypass), and multi-port energy routing capabilities compared to conventional solutions. Additional potential implementations or possibly related variations of the FPPA cell 150 are described or shown in PCT Application No. PCT/US26/13655, filed Feb. 3, 2026, at least at FIGS. 2A, 2B, and 3A-3D of the Drawings and paragraphs [0039]-[0045] of the Specification, the entire disclosure of which is hereby incorporated herein by reference.

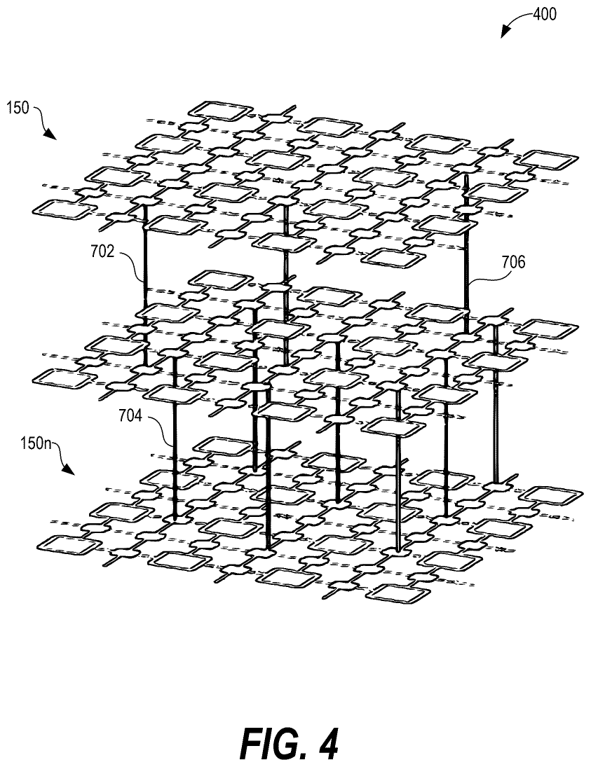

FIG. 3 depicts a schematic of an example multi-phase FPPA system 300 for enabling bidirectional power flow, and FIG. 4 depicts switch interconnect fabric 400 of the multi-phase FPPA system 300 interconnecting AC-side subcells and DC-side subcells among multiple FPPA cells to each other, according to various embodiments. The multi-phase FPPA system 300 can be implemented in both HVDC and MVDC power converter systems and applications and can include multiple FPPA cells 150a to 150n (with “n” being a whole number) coupled together in a reconfigurable manner at AC and DC ports for each phase leg of the multi-phase FPPA system 300. Each of the FPPA cells 150a to 150n is substantially similar to the FPPA cell 150. The various reconfigurable coupling configurations are described in further detail below.

As described with respect to the FPPA system 100, each FPPA cell can be coupled between an AC port and two DC ports (DC port 1 and DC port 2) as illustrated. However, the AC-side subcell(s) 102 (e.g., AC-side subcells 102a to 102n with “n” being a whole number) for each FPPA cell (e.g., cell 150 or cell 150n) can be expanded to include multiple AC-side subcells that are connected in parallel or series at the AC port within the cell. Additionally, the DC-side subcell(s) 106 (e.g., DC-side subcells 106a to 106n) for each FPPA cell can be expanded to include multiple DC-side subcells that are connected in parallel or series at the DC port 1 within the cell, and the DC-side subcell(s) 108 (e.g., DC-side subcells 108a to 108n) for each FPPA cell can be expanded to include multiple DC-side subcells that are connected in parallel or series at the DC port 2 within the cell.

In an example configuration for HVDC handling, for each cell, the AC-side subcells 102 may be connected in parallel to the AC port, the DC-side subcells 106 may be connected in series to the DC port 1, and the DC-side subcells 108 may be connected in series to the DC port 2. However, the FPPA system 300 is not limited thereto and the AC-side subcells 102, the DC-side subcells 106, and the DC-side subcells 108 for each cell can be dynamically recoupled into other configurations based on instructions received from the controller 10.

Multiple FPPA cells within a phase leg can be coupled to each other in various configurations. Referring to FIG. 4, the FPPA system 300 can include a switch interconnect fabric 400 for interconnecting the FPPA cells 150a to 150n to each other via interconnect structures 702, 704, and 706. The switch interconnect fabric 400 (also referred to as an interconnect network, switching fabric, or switch matrix) can be configured to provide selectable electrical coupling among power switches and/or converter cells. The switch interconnect fabric can include a plurality of conductive interconnects (e.g., busbars, backplane conductors, cables, printed circuit board traces, or combinations thereof) and a plurality of controllable switching elements (e.g., semiconductor switches, contactors, relays, solid-state switches, or combinations thereof) arranged to form multiple selectable current paths.

In some examples, the switch interconnect fabric 400 can include a plurality of fabric nodes and fabric links. Each converter cell can be coupled to the switch interconnect fabric via one or more cell terminals (e.g., an AC terminal, one or more DC terminals, and/or internal midpoints). The fabric links can include one or more conductors providing electrical connectivity between fabric nodes, and the switch interconnect fabric can further include one or more selectable coupling elements positioned on the fabric links and/or at the fabric nodes. The selectable coupling elements can be controlled to open, close, or modulate coupling between selected nodes to implement a commanded topology.

In some examples, the switch interconnect fabric 400 can be configured to interconnect power switches among different power converter cells to enable (i) reconfiguration of cell-to-cell connectivity (e.g., series, parallel, bypassed, inserted), (ii) selective routing of current between cells, and/or (iii) isolation of a cell or switch from one or more ports. For example, the switch interconnect fabric 400 can selectively couple a first node of a first converter cell to a corresponding node of a second converter cell, while decoupling that first node from a third converter cell, based on a commanded operating mode.

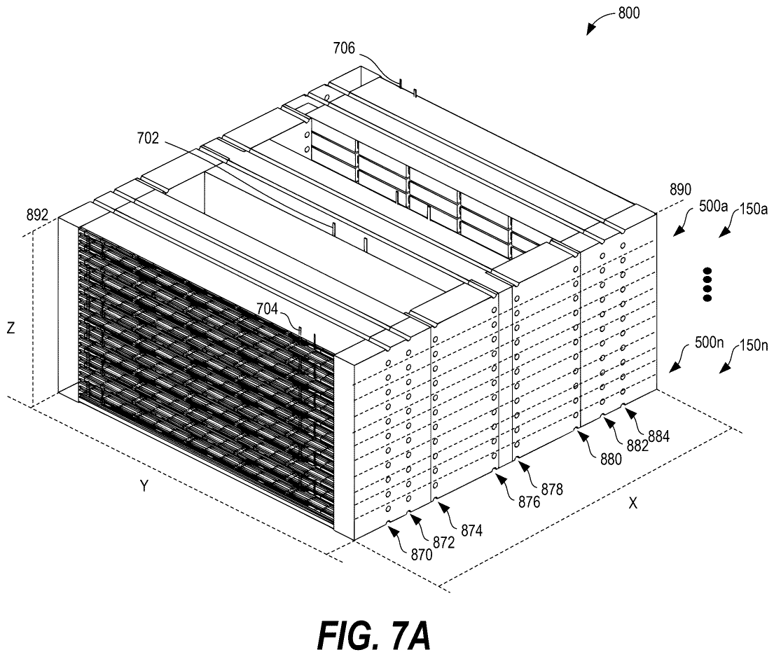

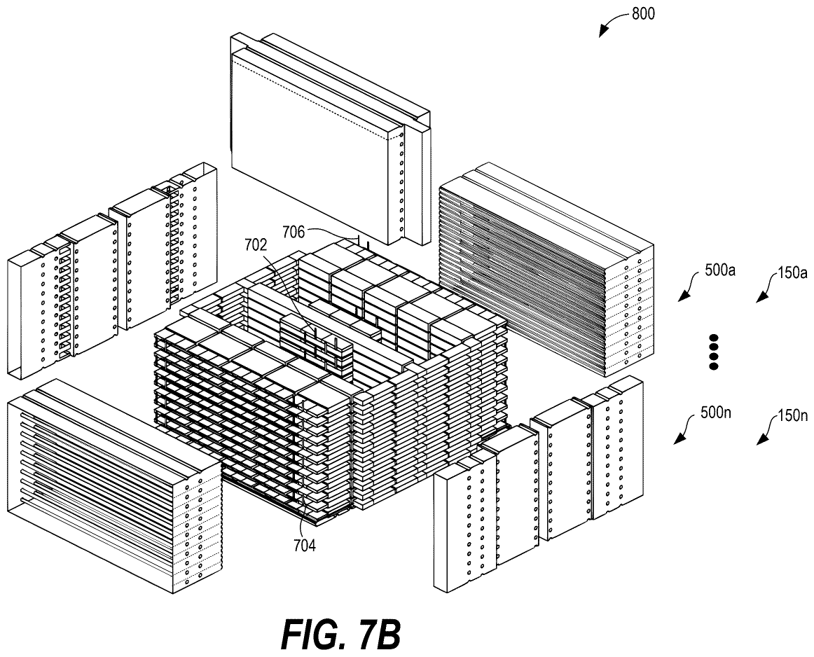

The switch interconnect fabric 400 shown in FIG. 7 is provided for representative purposes only. Other interconnect fabrics having different numbers, arrangements, and/or types of interconnections and switching elements may be used without departing from the scope of the present disclosure. In the example shown, the interconnect structure 702 can couple the AC-side subcells 102 among the multiple FPPA cells (e.g., cells 150a to 150n) to each other, the interconnect structure 704 can couple the DC-side subcells 106 among the multiple FPPA cells to each other, and the interconnect structure 706 can couple the DC-side subcells 108 among the multiple FPPA cells to each other.

The controller 10 can be configured to direct the switch interconnect fabric 400 to dynamically reconfigure coupling configurations of the AC-side subcells 102 among the multiple FPPA cells (e.g., cells 150a to 150n for phase A, B, or C) between series and parallel configurations at the AC port. The controller 10 can be configured to direct the switch interconnect fabric 400 to dynamically reconfigure coupling configurations of the DC-side subcells 106 among the multiple FPPA cells between series and parallel configurations at the DC port 1. The controller 10 can be configured to direct the switch interconnect fabric 400 to dynamically reconfigure coupling configurations of the DC-side subcells 108 among the multiple FPPA cells between series and parallel configurations at the DC port 2.

The controller 10 can also be configured to direct the switch interconnect fabric 400 to bypass certain cells among the multiple FPPA cells in response to detection of faults. For example, the controller 10 may detect a fault at the FPPA cell 150 and can direct the switch interconnect fabric 400 to bypass the cell 150 so that energy would not flow therein and be rerouted to other cells in the FPPA system 300. Any power converter cell or FPPA cell in which a fault is detected can be bypassed or shorted for series connections (e.g., by shorting the two AC terminals for the AC side or shorting the two DC terminals on the DC side). For power converter cells connected in parallel, any power converter cell or cell components can be bypassed or disconnected (e.g., by disconnecting corresponding AC terminals for the AC side or disconnecting corresponding DC terminals on the DC side).

Each phase leg (e.g., corresponding to phase A, phase B, and phase C) may generate single-phase ripple power and in three-phase operation as shown by the system 300, these single-phase ripple powers may be cancelled out with each other by coupling in parallel the DC port 1 of each of the phase legs, and the DC port 2 of each of the phase legs.

The following provides exemplary embodiments of an FPPA cell or FPPA system. In one example, multiple subcells of an FPPA cell can be connected together in parallel and series on the primary and secondary sides, respectively, of a transformer (e.g., the transformer 104) to create a submodule (e.g., implementable in the HVDC converter station 1000 or MVDC converter systems) with matched AC and DC port voltages (e.g., 2 kV). Multiple submodules can be stacked together on both the AC and DC ports in the same tower to create a module (e.g., rated at 30±kV). A multi-port or multi-phase FPPA system on a high voltage (e.g., ±525 kV) DC grid can be created with FPPA submodules connected in series in the AC port and DC ports. Bypass at AC and DC ports at FPPA cell and VSM levels are designed to achieve fault-tolerant operation and high system reliability, as discussed above.

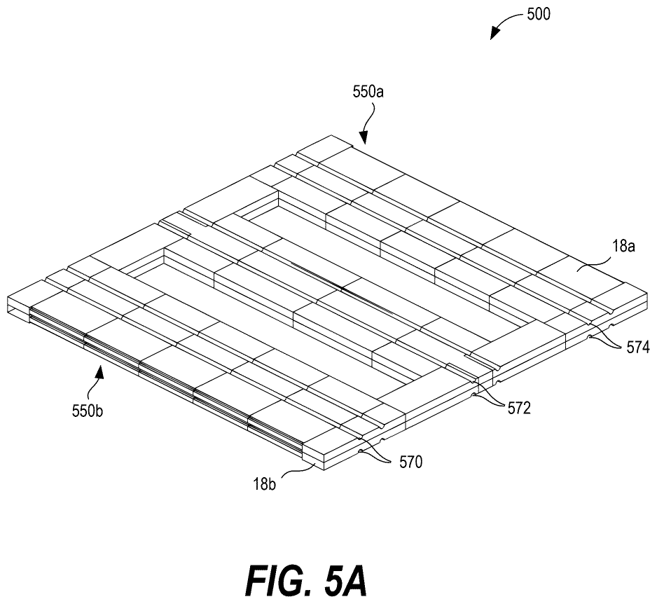

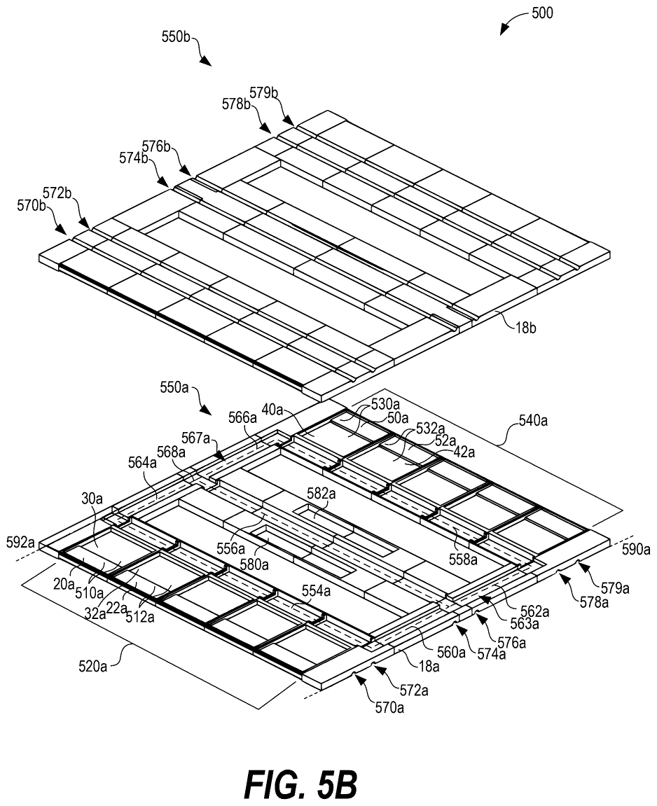

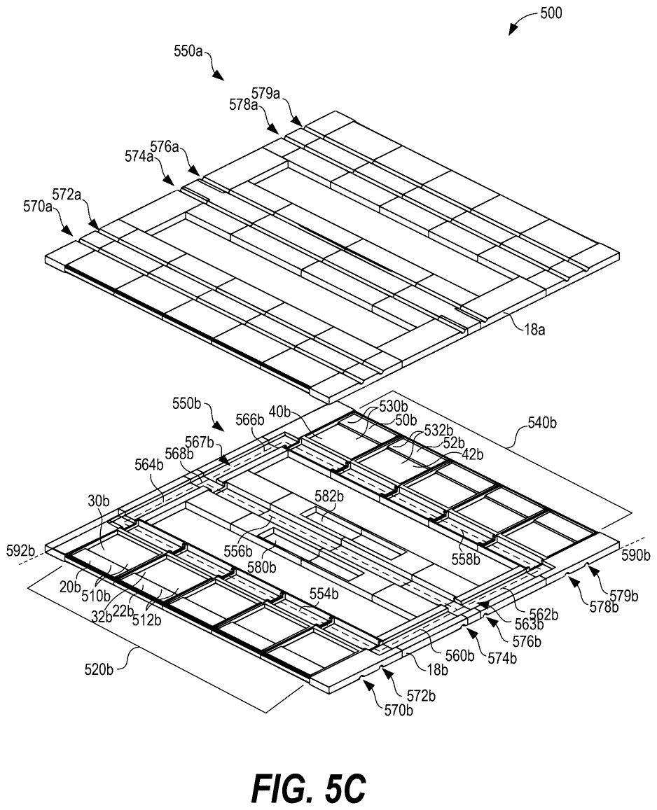

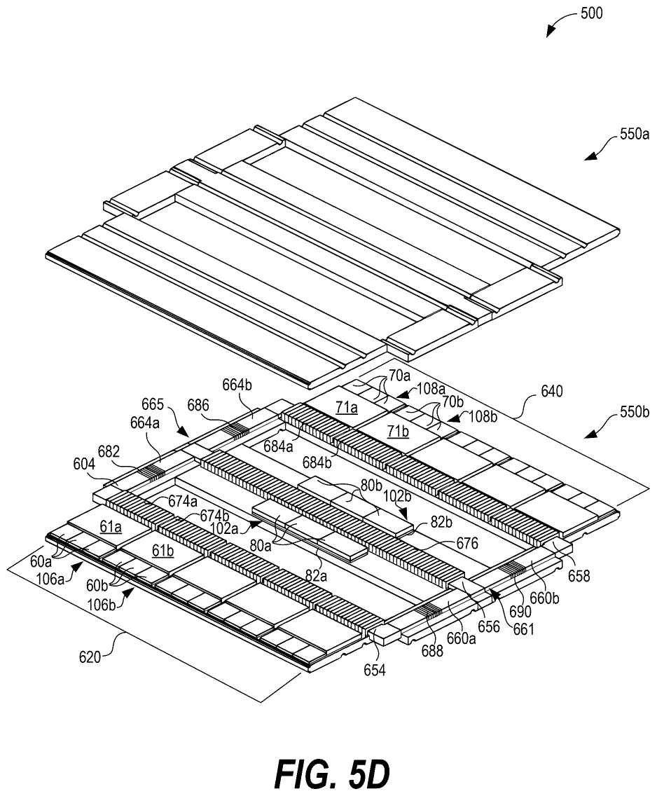

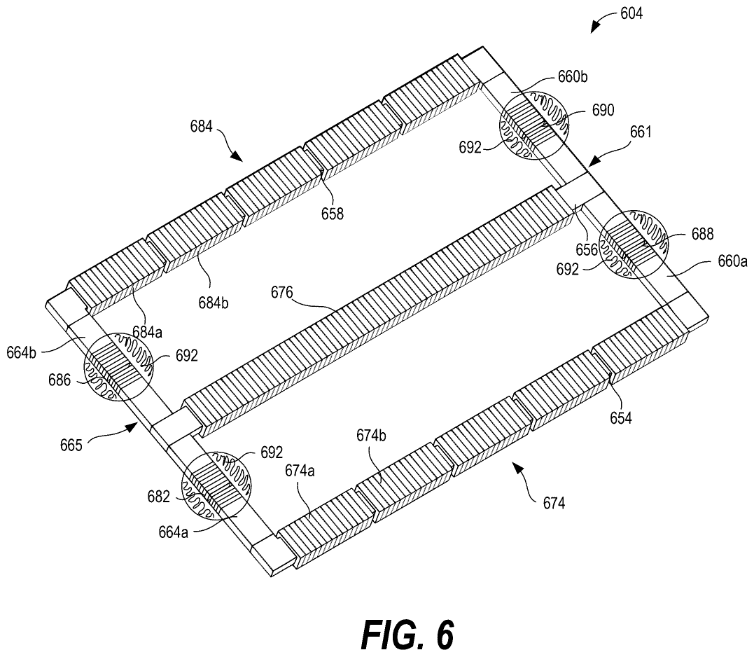

FIG. 5A depicts an FPPA housing 500, FIG. 5B depicts an exploded view of the FPPA housing 500 with an interior of a lower housing shell layer exposed, FIG. 5C depicts the FPPA housing shown in FIG. 5B flipped upside down to show an interior of an upper housing layer exposed, and FIG. 5D depicts an exploded view of the FPPA housing 500 with subcells positioned therein. FIG. 6 depicts a magnetic core 604 (e.g., of the transformer 104) with IMECs according to various embodiments. The FPPA housing 500 can include a first housing shell layer 550a and a second housing shell layer 550b. The first housing shell layer 530 can also be an upper housing shell layer, and the second housing shell layer 550b can be a lower housing shell layer of the FPPA housing 500, or vice-versa. The first housing shell layer 550a and the second housing shell layer 550b are substantially similar to each other in structure and may be interchangeable with each other. For example, interiors and exteriors of the first housing shell layer 550a and the second housing shell layer 550b are substantially similar to each other in structure.

The FPPA housing 500 can include an FPPA cell or an FPPA submodule, such as the FPPA cell 150. For example, various circuitry regarding the FPPA cell 150, including the AC-side subcells, DC-side subcells, magnetic cores, and windings, can be implemented into the FPPA housing 500, to form an FPPA submodule for use in the HVDC converter station 1000. The FPPA housing 500 can be coupled between an AC port and two DC ports as shown in FIGS. 2 and 3 for connection to an AC yard and two DC yards as shown in FIG. 1, for various HVDC power conversion applications and/or MVDC power conversion applications.

The FPPA housing 500 is significantly bulk ceramic, and each of the AC-side subcells, DC-side subcells, and transformer (e.g., such as the core and windings) of the FPPA cell 150 can be encapsulated in the FPPA housing 500 by the bulk ceramic. The bulk ceramic housing provides excellent electrical insulation barriers and thermal conductive paths for the FPPA cell 150 positioned therein. The bulk ceramic housing, which can include ceramic such as alumina (e.g., 99.5% Al₂O₃) provides properties such as high dielectric strength (e.g., approximately 10-20 kV/mm) and high thermal conductivity (e.g., approximately 20-30 W/m K), especially compared to other dielectric materials that either provide high dielectric strength and low thermal conductivity, or high thermal conductivity and low dielectric strength.

Insulation materials, insulation and thermal management systems, and structural designs are some of the biggest challenges for HVDC converters. Effective insulation systems that can handle high power dissipation and high voltage stress (e.g., over 1000 kV) between AC and DC ports is needed for HVDC applications. The FPPA housing 500 is significantly bulk ceramic, and the dielectric strength and thermal conductivity of bulk ceramic is exemplified below, compared to other dielectric materials:

TABLE 1
Comparison of Dielectric Strength and Thermal Conductivity
of Gas, Liquid, and Solid Materials

| | | Dielectric Strength | Thermal Conductivity |
|---|---|---|---|
| Phase | Material | (kV/mm) | (W/m · K) |
| Gas | Air | 3 | 0.025 |
| | SF₆ | 7.5-8 | 0.0136 |
| | G³ gas | Lower than SF₆ | Similar to SF₆ |
| Liquid | De-ionized water | ~5 | 0.6 |
| | Transformer oil | 30 | 0.12 |
| Solid | Ceramic Al₂O₃ | 10-20 | 20-30 |
| | FR4 | 15-25 | 0.25-0.4 |
| | Epoxy resin | 16.5-19 | 0.17-0.21 |
| | Epoxy with nano- | 5 | 0.5-35 |
| | filler | | |
| | Kapton | 300 | 0.2 |

Bulk ceramic housing can be designed and machined with features to accommodate AC-side subcells, DC-side subcells, magnetic cores and windings, auxiliary electronics, and bus bars. Epoxy with nano-filler can be used to bond these components to the bulk ceramic housing. Bulk ceramic housing may be formed by joining multiple smaller piece of ceramic together with processes such as brazing or chemical bonding.

The first housing shell layer 550a and the second housing shell layer 550b can be integrally formed with each other or may be separable and able to be combined, sealed, or mated together to form the FPPA housing 500. The first housing shell layer 550a can be positioned over the second housing shell layer 550b, or vice-versa, to form DC-side cavities, AC-side cavities, and a magnetic core cavity for positioning the DC-side subcells, the AC-side subcells, and the magnetic core, respectively, of the FPPA cell 150, as described below.

The description below provides references and labels to “upper” and “lower” DC-side cavities, “upper” and “lower” AC-side cavities, an “upper” and “lower” magnetic core cavity, and other components, for each of the first housing shell layer 550a and the second housing shell layer 550b. It should be understood that each of the first housing shell layer 550a and the second housing shell layer 550b includes “upper” or “lower” DC-side cavities, “upper” or “lower” AC-side cavities, “upper” or “lower” magnetic core cavity, and other “upper′ or “lower” components, and the combining (e.g., mating, sealing, etc.) of the first and second housing shell layers 550a and 550b provides a “first DC-side cavity,” a “second DC-side cavity,” an “AC-side cavity,” a “magnetic core cavity,” and so forth. When the first housing shell layer 550a and the second housing shell layer 550b are combined, an FPPA cell (e.g., the FPPA cell 150) therein is encapsulated by the bulk ceramic. The FPPA housing 500 is not exhaustively illustrated, meaning that one or more components not shown can be included in some cases. Alternatively, some components shown in the FPPA housing 500 may be omitted in practice.

The first housing shell layer 550a includes a first array of upper DC-side cavities 520a for positioning a first array of DC-side subcells 620 (FIG. 5D) therein. The first array of upper DC-side cavities 520a can include a first upper DC-side cavity 510a, a second upper DC-side cavity 512a, and additional upper DC-side cavities as shown.

The first array of DC-side subcells 620 can include the DC-side subcell 106a, a DC-side subcell 106b, and additional DC-side subcells coupled in series or parallel to DC port 1 (FIGS. 2 and 3). The DC-side subcell 106a can include control circuitry 60a and switching circuitry 61a, and the DC-side subcell 106b can include control circuitry 60b and switching circuitry 61b. Each of the control circuitries 60a and 60b can include bypass circuitry and auxiliary circuitry for facilitating bypass functions, switching control functions, and energy rerouting functions of the switching circuitry 61a or 61b of the corresponding DC-side subcell, as described herein.

Each upper DC-side cavity includes an upper pocket for positioning switching transistors of a DC-side subcell and a connected upper ridge for positioning control circuitry of the DC-side subcell. For example, the first upper DC-side cavity 510a includes an upper pocket 30a and an upper ridge 20a for possibly positioning the switching circuitry 61a and the control circuitry 60a, respectively, of the DC-side subcell 106a. The second upper DC-side cavity 512a includes an upper pocket 32a and an upper ridge 22a for possibly positioning the switching circuitry 61b and the control circuitry 60b, respectively, of the DC-side subcell 106b.

The first housing shell layer 550a includes a second array of upper DC-side cavities 540a for positioning a second array of DC-side subcells 640 (FIG. 5D) therein. The second array of upper DC-side cavities 540a can include a first upper DC-side cavity 530a, a second upper DC-side cavity 532b, and additional upper DC-side cavities as shown.

The second array of DC-side subcells 640 can include the DC-side subcell 108a, a DC-side subcell 108b, and additional DC-side subcells coupled in series or parallel to DC port 2 (FIGS. 2 and 3). The DC-side subcell 108a can include control circuitry 70a and switching circuitry 71a, and the DC-side subcell 108b can include control circuitry 70b and switching circuitry 71b. Each of the control circuitries 70a and 70b can include bypass circuitry and auxiliary circuitry for facilitating bypass functions, switching control functions, and energy rerouting functions of the switching circuitry 71a or 71b of the corresponding DC-side subcell, as described herein.

Each upper DC-side cavity includes an upper pocket for positioning switching transistors of a DC-side subcell and a connected upper ridge for positioning control circuitry of the DC-side subcell. For example, the first upper DC-side cavity 530a includes an upper pocket 40a and an upper ridge 50a for possibly positioning the switching circuitry 71a and the control circuitry 70a, respectively, of the DC-side subcell 108a. The second upper DC-side cavity 532a includes an upper pocket 42a and an upper ridge 52a for possibly positioning the switching circuitry 71b and the control circuitry 70b, respectively, of the DC-side subcell 108b.

The second housing shell layer 550b includes a first array of lower DC-side cavities 520b for positioning the first array of DC-side subcells 620 (FIG. 5D) therein. The first array of lower DC-side cavities 520b can include a first lower DC-side cavity 510b, a second lower DC-side cavity 512b, and additional lower DC-side cavities as shown. Each lower DC-side cavity includes a lower pocket for positioning switching transistors of a DC-side subcell and a connected lower ridge for positioning control circuitry of the DC-side subcell. For example, the first lower DC-side cavity 510b includes a lower pocket 30b and a lower ridge 20b for possibly positioning the switching circuitry 61a and the control circuitry 60a, respectively, of the DC-side subcell 106a. The second upper DC-side cavity 512b includes a lower pocket 32b and a lower ridge 22b for possibly positioning the switching circuitry 61b and the control circuitry 60b, respectively, of the DC-side subcell 106b.

The second housing shell layer 550b includes a second array of upper DC-side cavities 540b for positioning the second array of DC-side subcells 640 (FIG. 5D) therein. The second array of upper DC-side cavities 540b can include a first upper DC-side cavity 530b, a second upper DC-side cavity 532b, and additional upper DC-side cavities as shown. Each upper DC-side cavity includes an upper pocket for positioning switching transistors of a DC-side subcell and a connected upper ridge for positioning control circuitry of the DC-side subcell. For example, the first upper DC-side cavity 530b includes an upper pocket 40b and an upper ridge 50b for possibly positioning the switching circuitry 71a and the control circuitry 70a, respectively, of the DC-side subcell 108a. The second upper DC-side cavity 532b includes an upper pocket 42b and an upper ridge 52b for possibly positioning the switching circuitry 71b and the control circuitry 70b, respectively, of the DC-side subcell 108b.

The first housing shell layer 550a includes a first upper AC-side cavity 580a and a second upper AC-side cavity 582a for positioning the AC-side subcell 102a and an AC-side subcell 102b therein, respectively. The AC-side subcells 102a and 102b can be coupled in parallel or series to the AC port (FIGS. 2 and 3) The upper AC-side cavities 580a and 582a are positioned between the first array of upper DC-side cavities 520a and the second array of upper DC-side cavities 540a. The AC-side subcell 102a includes control circuitry 80a and switching circuitry 82a stacked on (below or above depending on orientation) the control circuitry 80a. The AC-side subcell 102b includes control circuitry 80b and switching circuitry 82b stacked on (below or above depending on orientation) the control circuitry 80b.

The second housing shell layer 550b includes a first lower AC-side cavity 580b and a second lower AC-side cavity 582b for positioning the AC-side subcell 102a and the AC-side subcell 102b therein, respectively. The lower AC-side cavities 580b and 582b are positioned between the first array of lower DC-side cavities 520b and the second array of lower DC-side cavities 540b.

The first housing shell layer 550a includes an upper magnetic core cavity 568a as indicated by the dotted or dashed lines for positioning the magnetic core 604 (FIG. 6) therein. The magnetic core 604 can be a core of the transformer 104, for example, and can include ferrite cores or nanocrystalline cores, as discussed. The magnetic core 604 is of an “EI” shape as shown for exemplary purposes but can include other shapes such as “E” shape, “U” shape, “UI” shape, toroidal shape, or other shapes. The magnetic core 604 includes a first DC-side core leg 654, a second DC-side core leg 658, and an AC-side core leg 656 between the DC-side core legs 654 and 658. The magnetic core 604 includes a first yoke 661 interconnecting the DC-side core legs 654 and 658 and the AC-side core leg 656. The first yoke 661 includes a first yoke part 660a and a second yoke part 660b. The magnetic core 604 can include a second yoke 665 interconnecting the DC-side core legs 654 and 658 and the AC-side core leg 656. The second yoke 665 includes a first yoke part 664a and a second yoke part 664b.

The magnetic core 604 includes a first array of DC-side windings 674 on the first DC-side core leg 654. The first array of DC-side windings 674 includes a first DC-side winding 674a, a second DC-side winding 674b, and additional DC-side windings, for coupling to the first array of DC-side subcells 620. The magnetic core 604 includes a second array of DC-side windings 684 on the second DC-side core leg 658. The second array of DC-side windings 684 includes a first DC-side winding 684a, a second DC-side winding 684b, and additional DC-side windings, for coupling to the second array of DC-side subcells 640. The magnetic core 604 includes an AC-side winding 676 on the AC-side core leg 656, for coupling to the AC-side subcells 102a and 102b.

The magnetic core 604 includes insulated magnetic energy couplers (IMECs) 684, 686, 688, and 690 between the DC-side core legs 654 and 658 and the AC-side core leg 656. Each of the IMECs 684, 686, 688, and 690 include slices of magnetic cores sandwiched with thin slices of high dielectric strength material layers, such as polyimide layers. The high dielectric strength material layers serve as distributed “air” gaps for the MF/HF transformer (e.g., transformer 104). The thin thickness of the high dielectric material layers enables maximized utilization of insulation capability of the dielectric material, and at the same time provides low leakage inductances for the transformer due to low leakage flux around the thin dielectric layers. The IMEC structure provides high system voltage blocking capability for each FPPA module, high power transfer capability for the transformer, and ease handling of power loss, as the result of the structure allows decoupled functionalities of insulation, electromagnetic energy transfer, and power dissipation.

The magnetic core 604 includes the IMEC 684 at the first yoke part 664a between the AC-side core leg 656 and the first DC-side core leg 654. The magnetic core 604 includes the IMEC 686 at the second yoke part 664b between the AC-side core leg 656 and the second DC-side core leg 658. The magnetic core 604 includes the IMEC 688 at the first yoke part 660a between the AC-side core leg 656 and the first DC-side core leg 654. The magnetic core 604 includes the IMEC 690 at the second yoke part 660b between the AC-side core leg 656 and the second DC-side core leg 658. Each of the IMECs 682, 686, 688, and 690 include a plurality of distributed gaps. Each distributed gap includes or is filled with polyimide film, such as Kapton® tape, which provides high dielectric strength (e.g., 150-300 kV/mm).

The IMECs 682, 686, 688, and 690 are positioned strategically between each of the core legs 654, 656, and 658 at parts of the yokes for efficient energy coupling and HV insulation between AC and DC ports. For example, energy transfer can occur between AC and DC ports via MF or HF transformers with galvanic isolation in the FPPA systems 100 and 300. Thus, HV insulation can be required between the AC and DC ports in the FPPA systems. The IMECs 682, 686, 688, and 690 can provide HV insulation (e.g., for over 1000 kV) and efficient energy coupling between the AC and DC ports. In addition to the plurality of distributed gaps filled with polyimide film for each of the IMECs 682, 686, 688, and 690, polyimide film or other high dielectric strength material 692 may need to be wrapped around the plurality of distributed gaps for each of the IMECs 682, 686, 688, and 690, for further insulation and to prevent the IMECs 682, 686, 688, and 690 from being exposed to air. The IMECs 682, 686, 688, and 690 can enable close positioning of the winding arrays 674 and 684 and the winding 676 to the magnetic core 604.

The upper magnetic core cavity 568a runs in an “EI” shape for positioning an “EI” shaped magnetic core, for example. The EI shape for the magnetic core cavity 568a is shown for exemplary purposes only, and the magnetic core cavity 568a can be formed of a variety of shapes to position the magnetic core of the transformer 104 therein, such as “E” shape, “U” shape, “UI” shape, toroidal shape, or other shapes. The upper magnetic core cavity 568a can include a first upper DC-side core leg cavity 554a for positioning the first DC-side core leg 654, a second upper DC-side core leg cavity 558a for positioning the DC-side core leg 658, an upper AC-side core leg cavity 556a between the first upper DC-side core leg cavity 554a and the second upper DC-side core leg cavity 558a for positioning the AC-side core leg 656, a first upper yoke cavity 567a for positioning the second yoke 665, and a second upper yoke cavity 563a for positioning the first yoke 661.

The first upper yoke cavity 567a includes a first upper yoke part cavity 564a for positioning the first yoke part 664a and a second upper yoke part cavity 566a for positioning the second yoke part 664b. The second upper yoke cavity 563a includes a first upper yoke part cavity 560a for positioning the first yoke part 660a and a second upper yoke part cavity 562a for positioning the second yoke part 660b.

The first upper DC-side core leg cavity 554a can be used to position the first array of DC-side windings 674 therein. The first upper DC-side core leg cavity 554a can be partitioned into multiple parts for positioning each of the first array of DC-side windings 674. The second upper DC-side core leg cavity 558a can be used to position the second array of DC-side windings 684 therein. The second upper DC-side core leg cavity 558a can be partitioned into multiple parts for positioning each of the second array of DC-side windings 684. The upper AC-side core leg cavity 556a can be used to position the AC-side winding 676 therein.

The second housing shell layer 550b includes a lower magnetic core cavity 568b as indicated by the dotted or dashed lines for positioning the magnetic core 604 (FIG. 6) therein. The lower magnetic core cavity 568b runs in an “EI” shape for positioning an “EI” shaped magnetic core, for example. The EI shape for the lower magnetic core cavity 568b is shown for exemplary purposes only, and the magnetic core cavity 568b can be formed of a variety of shapes to position the magnetic core of the transformer 104 therein, such as “E” shape, “U” shape, “UI” shape, toroidal shape, or other shapes. The lower magnetic core cavity 568b can include a first lower DC-side core leg cavity 554b for positioning the first DC-side core leg 654, a second lower DC-side core leg cavity 558b for positioning the DC-side core leg 658, an upper AC-side core leg cavity 556b between the first lower DC-side core leg cavity 554b and the second lower DC-side core leg cavity 558b for positioning the AC-side core leg 656, a first lower yoke cavity 567b for positioning the second yoke 665, and a second lower yoke cavity 563b for positioning the first yoke 661.

The first lower yoke cavity 567b includes a first lower yoke part cavity 564b for positioning the first yoke part 664a and a second lower yoke part cavity 566b for positioning the second yoke part 664b. The second lower yoke cavity 563b includes a first lower yoke part cavity 560b for positioning the first yoke part 660a and a second lower yoke part cavity 562b for positioning the second yoke part 660b.

The first lower DC-side core leg cavity 554b can be used to position the first array of DC-side windings 674 therein. The first lower DC-side core leg cavity 554b can be partitioned into multiple parts for positioning each of the first array of DC-side windings 674. The second lower DC-side core leg cavity 558b can be used to position the second array of DC-side windings 684 therein. The second lower DC-side core leg cavity 558b can be partitioned into multiple parts for positioning each of the second array of DC-side windings 684. The lower AC-side core leg cavity 556b can be used to position the AC-side winding 676 therein.

When the first housing shell layer 550a is positioned over and combined with the second housing shell layer 550b, the first array of upper DC-side cavities 520a is positioned over the first array of lower DC-side cavities 520b to form a first array of DC-side cavities 520. Similarly, the first upper DC-side cavity 510a is positioned over the first lower DC-side cavity 510b to form a first DC-side cavity 510. Similarly, the second upper DC-side cavity 512a is positioned over the second lower DC-side cavity 512b to form a second DC-side cavity 512. Similarly, the upper magnetic core cavity 568a is positioned over the lower magnetic core cavity 568b to form a magnetic core cavity 568. Similarly, the second upper AC-side cavity 582a is positioned over the second lower AC-side cavity 582b to form a second AC-side cavity 582. Similarly, the first upper AC-side cavity 580a is positioned over the first lower AC-side cavity 580b to form a first AC-side cavity 580.

Similarly, the second array of upper DC-side cavities 540a is positioned over the second array of lower DC-side cavities 540b to form a second array of DC-side cavities 540. Similarly, the first upper DC-side cavity 530a is positioned over the first lower DC-side cavity 530b to form a first DC-side cavity 530. Similarly, the second upper DC-side cavity 532a is positioned over the second lower DC-side cavity 532b to form a second DC-side cavity 532. In this way, each “upper” component of the first housing shell layer 550a and each “lower” component of the second housing shell layer 550b can be combined to form a single component in various embodiments.

The first housing shell layer 550a includes a first outer shell layer 18a. The first outer shell layer 18a includes a first end 590a and an opposite second end 592a, and the first array of upper DC-side cavities 520a, the first upper DC-side core leg cavity 554a, the first upper AC-side cavity 580a, the second upper AC-side cavity 582a, the upper magnetic core cavity 568a, the second upper DC-side core leg cavity 558a, and the second array of upper DC-side cavities 540a are between the first end 590a and the opposite second end 592a.

The first outer shell layer 18a includes a first upper embedded cooling channel 570a extending from the first end 590a to the opposite second end 592a and over/under the first array of upper DC-side cavities 520a, a second upper embedded cooling channel 572a extending from the first end 590a to the opposite second end 592a and over/under the first array of upper DC-side cavities 520a, a third upper embedded cooling channel 574a extending from the first end 590a to the opposite second end 592a and over/under the first upper AC-side cavity 580a, a fourth upper embedded cooling channel 576a extending from the first end 590a to the opposite second end 592a and over/under the second upper AC-side cavity 582a, a fifth upper embedded cooling channel 578a extending from the first end 590a to the opposite second end 592a and over/under the second array of upper DC-side cavities 540a, and a sixth upper embedded cooling channel 579a extending from the first end 590a to the opposite second end 592a and over/under the second array of upper DC-side cavities 540a.

The second housing shell layer 550b includes a second outer shell layer 18b. The second outer shell layer 18b includes a first end 590b and an opposite second end 592b, and the first array of lower DC-side cavities 520b, the first lower DC-side core leg cavity 554b, the first lower AC-side cavity 580b, the second lower AC-side cavity 582b, the lower magnetic core cavity 568b, the second lower DC-side core leg cavity 558b, and the second array of lower DC-side cavities 540b are between the first end 590b and the opposite second end 592b.

The second outer shell layer 18b includes a first lower embedded cooling channel 570b extending from the first end 590b to the opposite second end 592b and over/under the first array of lower DC-side cavities 520b, a second lower embedded cooling channel 572b extending from the first end 590b to the opposite second end 592b and over/under the first array of lower DC-side cavities 520b, a third lower embedded cooling channel 574b extending from the first end 590b to the opposite second end 592b and over/under the first lower AC-side cavity 580b, a fourth lower embedded cooling channel 576b extending from the first end 590b to the opposite second end 592b and over/under the second lower AC-side cavity 582b, a fifth lower embedded cooling channel 578b extending from the first end 590b to the opposite second end 592b and over/under the second array of lower DC-side cavities 540b, and a sixth lower embedded cooling channel 579b extending from the first end 590b to the opposite second end 592b and over/under the second array of lower DC-side cavities 540b.

The “upper” and “lower” cooling channels of the first and second housing shell layers (e.g., the first upper embedded cooling channel 570a and the first lower embedded cooling channel 570b) are symmetrically aligned with each other when the first housing shell layer 550a and the second housing shell layer 550b are combined or sealed/mated together. In this way, the first upper embedded cooling channel 570a and the first lower embedded cooling channel 570b can form a first embedded cooling channel 570, the second upper embedded cooling channel 572a and the second lower embedded cooling channel 572b can form a second embedded cooling channel 572, the third upper embedded cooling channel 574a and the third lower embedded cooling channel 574b can form a third embedded cooling channel 574, the fourth upper embedded cooling channel 576a and the fourth lower embedded cooling channel 576b can form a fourth embedded cooling channel 576, the fifth upper embedded cooling channel 578a and the fifth lower embedded cooling channel 578b can form a fifth embedded cooling channel 578, and the sixth upper embedded cooling channel 579a and the sixth lower embedded cooling channel 579b can form a sixth embedded cooling channel 579.

Each of the embedded cooling channels 570, 572, 574, 576, 578, and 579 can be machined into the first housing shell layer 550a and the second housing shell layer 550b at the outer shell layers 20a and 20b, respectively, and each of the embedded cooling channels 570, 572, 574, 576, 578, and 579 can provide passage for de-ionized water flow for thermal dissipation purposes. For example, heat generated from a result of power losses from power electronics (e.g., DC-side and AC-side subcells) can be removed via the embedded cooling channels 570, 572, 574, 576, 578, and 579.

In practice, the first housing shell layer 550a and the second housing shell layer 550b may be formed together integrally to form the FPPA housing 500 or combined or mated together and/or sealed to form the FPPA housing 500. The DC-side subcells, AC-side subcells, the magnetic core, and the windings on the magnetic core of the FPPA cell 150 inside the FPPA housing 500 are encapsulated by the bulk ceramic. These electronic/magnetic components can be bonded to the bulk ceramic housing through epoxy resin with nano-fillers, for example.

Magnetic core pieces, such as the first DC-side core leg 654 and the first array of DC-side windings 674 thereon, the second DC-side core leg 658 and the second array of DC-side windings 684 thereon, and the AC-side core leg 656 and the AC-side winding 676 thereon are positioned adjacent (within very close proximity) or on the first array of DC-side subcells 620, the second array of DC-side subcells 640, and the AC-side subcells 102a and 102b, respectively. These magnetic core pieces can be electrically connected (“grounded”) to a local subcell voltage potential. For example, magnetic core pieces on the DC sides of a subcell (e.g., the first DC-side core leg 654 and/or the first array of DC-side windings 674) may be connected to a corresponding positive or negative DC rails of the subcell (e.g., the DC-side subcells corresponding to the first array of DC-side subcells 620), and magnetic core pieces on the AC sides of a subcell (e.g., the AC-side core leg 656 and/or the AC-side winding 676) may be connected to either one of AC voltage terminals of the AC-side subcell 102a or the AC-side subcell 102b. This arrangement can result in reduced insulation distance for the core pieces of the magnetic core 604 and enable close positioning of the windings on the core legs.

FIG. 7A depicts an example FPPA housing 800 for an FPPA module, and FIG. 7B depicts an exploded view of the FPPA housing 800 according to various embodiments. It should be noted that the FPPA housing 800 is not drawn to scale and is not exhaustively illustrated, meaning that one or more components not shown can be included in some cases. Alternatively, one or more components shown can be omitted in some cases. The FPPA housing 800 can include a stack of submodules or a stack of FPPA cells, such as the FPPA cells 150a to 150n for example. As the housing 500 can include an FPPA cell, such as the FPPA cell 150, the FPPA housing 800 includes a plurality of FPPA housings 500a to 500n (with “n” being a whole number) stacked together to increase voltage handling capabilities of the FPPA systems (e.g., FPPA system 300) described herein for HVDC applications or MVDC applications.

The FPPA housing 800 is a modular housing and any number of FPPA housings 500 can be stacked on top of each other (with each housing including an FPPA cell or submodule) and sealed/mated together for HV insulation and energy transfer capabilities. The FPPA housing 800 includes a stack of embedded cooling channels 870, 872, 874, 876, 878, 880, 882, and 884 that extend from a first end 890 to an opposite second end 892 and over/under various power electronics components of each of the FPPA housings 500A to 500n, such as DC-side subcells and AC-side subcells.

The illustration of the FPPA housing 800 is shown for representative purposes only. The FPPA housing 800 can range in size depending on the implementation. In one example, the FPPA housing 800 may have dimensions of, approximately 1.74 meters in the “X” direction, approximately 1.78 meters in the “Y” direction, and approximately 0.84 meters in the “Z” direction, although the FPPA housing 800 can be formed to other sizes. The FPPA housing 800 and the module positioned therein may be rated for 30+kV for a ±525 kV FPPA system.

The power electronics components of each of the submodules of the housings 500a to 500n can be interconnected with each other by the switch interconnect fabric 400 (FIG. 4). For example, the interconnect structure 702 can couple the AC-side subcells 102 among the multiple FPPA cells (e.g., cells 150a to 150n that are in the FPPA housings 500a to 500n) to each other, the DC-side subcells 106 among the FPPA cells 150a to 150n to each other, and the DC-side subcells 108 among the FPPA cells 150a to 150n to each other.

The FPPA controller 10 can be configured to direct the switch interconnect fabric 400 to dynamically reconfigure coupling configurations of the AC-side subcells 102 among the multiple FPPA cells 150a to 150n between series and parallel configurations at the AC port. The controller 10 can be configured to direct the switch interconnect fabric 400 to dynamically reconfigure coupling configurations of the DC-side subcells 106 among the multiple FPPA cells 150a to 150n between series and parallel configurations at the DC port 1. The controller 10 can be configured to direct the switch interconnect fabric 400 to dynamically reconfigure coupling configurations of the DC-side subcells 108 among the multiple FPPA cells 150a to 150n between series and parallel configurations at the DC port 2.

The FPPA housing 800 including a module or a stack of submodules may be implemented in a tower of the HVDC converter station 1000 shown in FIG. 1. The FPPA housing 800 can be configured for HVDC applications or MVDC applications and can facilitate bidirectional energy flow, dynamic energy rerouting, and fault-tolerant operation for FPPA systems described herein.

The controller 10 can also be configured to direct the switch interconnect fabric 400 to bypass certain cells among the multiple FPPA cells in response to detection of faults. For example, the controller 10 may detect a fault at the FPPA cell 150 and can direct the switch interconnect fabric 400 to bypass the cell 150 so that energy would not flow therein and be rerouted to other cells in the FPPA system 300. Any power converter cell or FPPA cell in which a fault is detected can be bypassed or shorted for series connections (e.g., by shorting the two AC terminals for the AC side or shorting the two DC terminals on the DC side). For power converter cells connected in parallel, any power converter cell or cell components can be bypassed or disconnected (e.g., by disconnecting corresponding AC terminals for the AC side or disconnecting corresponding DC terminals on the DC side).

The FPPA systems 100 and 300, which can be implemented in the FPPA housings 500 or 800 can function as multi-port energy routers and can address key barriers limiting MMC-based HVDC converters and offer significant improvements in power density and cost reduction. MMC-based HVDC converters are limited by bulky and heavy line-frequency (LF) transformers (e.g., operating at 60 Hz) at an AC terminal and large “flying” capacitors in MMC valve submodules (VSM), which are required to handle single-phase double LF ripple power. These capacitors typically account for over 60 percent of an MMC VSM's size. Additionally, MMC-based HVDC converters are limited by extensive spacing requirements for air insulation because of the limited dielectric strength (e.g., 3 kV/mm) of air. Additional design margins may also be necessary to accommodate environmental factors such as elevation, humidity, and offshore conditions. Further, MMC-based HVDC converters require large air-core arm inductors, which are essential for proper MMC circuit operation.

The FPPA systems 100 and 300 implemented in the FPPA housings 500 or 800 effectively address the fundamental barriers limiting HVDC converters listed above by integrating a modular single-stage direct HF power conversion circuit and control, advanced insulation materials and design, HV engineering, and innovative packaging and thermal management. As a result, a high-power density solution with reduced footprint, volume, and cost can be implemented.

Further advantages of the FPPA systems 100 and 300, which can be implemented in the FPPA housings 500 or 800, include replacement of LF transformers. For example, traditional 60 Hz transformers can be replaced with compact, HF (e.g., 20 kHz) transformers. Bulky, single-phase “flying” capacitors can be eliminated. Each VSM's large capacitors can be replaced with significantly smaller three-phase DC link capacitors for example. The FPPA-based single-stage direct power conversion topology inherently cancels double LF ripple power when three-phase DC outputs combine at the DC port.

Insulation distances are significantly reduced. The described circuitry, insulation, and packaging designs minimize insulation gaps between FPPA cells, submodules, and modules at the AC and DC ports. The single-stage AC/DC/DC topology can ensure uniform voltage stress distribution, similar to conventional MMC-based HVDC converters. Only LV insulation (e.g., 500 V) may be required between FPPA Cells (e.g., FPPA cells 150a to 150n), while only MV insulation (e.g., 2 kV and 30 kV) may be required between FPPA submodules and modules based on implementation of bulk ceramic housing. Bulk ceramic housing has a 3-6× higher dielectric strength than air. Energy transfer between AC and DC ports can occur via HF transformers with galvanic isolation, eliminating direct electrical connections found in MMC-based HVDC converters.

The high system voltage insulation boundary is established through IMEC which features high dielectric strength (150-300 kV/mm). The insulation materials, system, and structure can be designed, modeled, and tested-especially for partial discharge under AC (sinusoidal and pulse-width-modulated) and DC conditions to ensure reliability, longevity (25-40 years), and environmental sustainability.

Large air-core arm inductors can be eliminated. Unlike MMC-based HVDC converters, an FPPA-based single-stage direct AC/DC/DC power conversion circuit does not require these inductors. Additionally, DC port filter inductors are unnecessary, as their function is integrated into the magnetizing inductance of the HF transformer using a current doubler rectifier and advanced magnetic design.

The features, structures, or characteristics described above may be combined in one or more embodiments in any suitable manner, and the features discussed in the various embodiments are interchangeable, if possible. In the following description, numerous specific details are provided in order to fully understand the embodiments of the present disclosure. However, a person skilled in the art will appreciate that the technical solution of the present disclosure may be practiced without one or more of the specific details, or other methods, components, materials, and the like may be employed. In other instances, well-known structures, materials, or operations are not shown or described in detail to avoid obscuring aspects of the present disclosure.

Although the relative terms such as “on,” “below,” “upper,” and “lower” are used in the specification to describe the relative relationship of one component to another component, these terms are used in this specification for convenience only, for example, as a direction in an example shown in the drawings. It should be understood that if the device is turned upside down, the “upper” component described above will become a “lower” component. When a structure is “on” another structure, it is possible that the structure is integrally formed on another structure, or that the structure is “directly” disposed on another structure, or that the structure is “indirectly” disposed on the other structure through other structures.

Terms such as “top,” “bottom,” “side,” “front,” “back,” “right,” “rear,” and “left” are not intended to provide an absolute frame of reference. Rather, the terms are relative and are intended to identify certain features in relation to each other, as the orientation of structures described herein can vary. The terms “comprising,” “including,” “having,” and the like are synonymous, are used in an open-ended fashion, and do not exclude additional elements, features, acts, operations, and so forth. Also, the term “or” is used in its inclusive sense, and not in its exclusive sense, so that when used, for example, to connect a list of elements, the term “or” means one, some, or all of the elements in the list.

When two components are described as being “coupled to” or “connected to” each other, the components can be electrically coupled or connected to each other, with or without other components being electrically coupled and intervening between them. When two components are described as being “directly coupled to” or “directly connected to” each other, the components can be electrically coupled or connected to each other, without other components being electrically coupled between them.

In this specification, the terms such as “a,” “an,” “the,” and “said” are used to indicate the presence of one or more elements and components. The terms “comprise,” “include,” “have,” “contain,” and their variants are used to be open ended, and are meant to include additional elements, components, etc., in addition to the listed elements, components, etc. unless otherwise specified in the appended claims. If a component is described as having “one or more” of the component, it is understood that the component can be referred to as “at least one” component.

The terms “first,” “second,” etc. are used only as labels, rather than a limitation for a number of the objects. It is understood that if multiple components are shown, the components may be referred to as a “first” component, a “second” component, and so forth, to the extent applicable.

The terms “about” and “substantially,” unless otherwise defined herein to be associated with a particular range, percentage, or related metric of deviation, account for at least some manufacturing tolerances between a theoretical design and manufactured product or assembly, such as the geometric dimensioning and tolerancing criteria described in the American Society of Mechanical Engineers (ASME®) Y14.5 and the related International Organization for Standardization (ISO®) standards. Such manufacturing tolerances are still contemplated, as one of ordinary skill in the art would appreciate, although “about,” “substantially,” or related terms are not expressly referenced, even in connection with the use of theoretical terms, such as the geometric “perpendicular,” “orthogonal,” “vertex,” “collinear,” “coplanar,” and other terms.

Disjunctive language such as the phrase “at least one of X, Y, or Z,” unless specifically stated otherwise, is otherwise understood with the context as used in general to present that an item, term, etc., can be either X, Y, or Z, or any combination thereof (e.g., X; Y; Z; X or Y; X or Z; Y or Z; X, Y, or Z; etc.). Thus, such disjunctive language is not generally intended to, and should not, imply that certain embodiments require at least one of X, at least one of Y, or at least one of Z to each be present.

One or more microprocessors, microcontrollers, or DSPs can execute software to perform the control aspects of the embodiments described herein, such as the control aspects performed by the FPPA controller 10. Any software or program instructions can be embodied in or on any suitable type of non-transitory computer-readable medium for execution. Example computer-readable mediums include any suitable physical (i.e., non-transitory or non-signal) volatile and non-volatile, random and sequential access, read/write and read-only, media, such as hard disk, floppy disk, optical disk, magnetic, semiconductor (e.g., flash, magneto-resistive, etc.), and other memory devices. Further, any component described herein can be implemented and structured in a variety of ways. For example, one or more components can be implemented as a combination of discrete and integrated analog and digital components.

The above-described embodiments of the present disclosure are merely possible examples of implementations set forth for a clear understanding of the principles of the disclosure. Many variations and modifications may be made to the above-described embodiment(s) without departing substantially from the spirit and principles of the disclosure. All such modifications and variations are intended to be included herein within the scope of this disclosure and protected by the following claims.

1. A field programmable power array (FPPA) housing, comprising:
a first housing shell layer, the first housing shell layer comprising a first upper direct current (DC)-side cavity, a second upper DC-side cavity, an upper alternating current (AC)-side cavity between the first upper DC-side cavity and the second upper DC-side cavity, and an upper magnetic core cavity; and
a second housing shell layer, the second housing shell layer comprising a first lower DC-side cavity, a second lower DC-side cavity, a lower AC-side cavity between the first lower DC-side cavity and the second lower DC-side cavity, and a lower magnetic core cavity.

2. The FPPA housing of claim 1, wherein when the first housing shell layer is positioned over the second housing shell layer:
the first upper DC-side cavity is positioned over the first lower DC-side cavity to form a first DC-side cavity;
the second upper DC-side cavity is positioned over the second lower DC-side cavity to form a second DC-side cavity;
the upper AC-side cavity is positioned over the lower AC-side cavity to form an AC-side cavity; and
the upper magnetic core cavity is positioned over the lower magnetic core cavity to form a magnetic core cavity.

3. (canceled)

4. The FPPA housing of claim 2, wherein the first DC-side cavity is a cavity among a first array of DC-side cavities, and the second DC-side cavity is a cavity among a second array of DC-side cavities.

5. The FPPA housing of claim 2, further comprising a first DC-side subcell positioned within the first DC-side cavity and a second DC-side subcell positioned within the second DC-side cavity.

6. The FPPA housing of claim 5, wherein:
the first lower DC-side cavity comprises a first lower ridge connected to a first lower pocket, and the first upper DC-side cavity comprises a first upper ridge connected to a first upper pocket; and
the second lower DC-side cavity comprises a second lower ridge connected to a second lower pocket, and the second upper DC-side cavity comprises a second upper ridge connected to a second upper pocket.

7. The FPPA housing of claim 6, wherein:
the first DC-side subcell comprises first switch circuitry and first control circuitry;
the first switch circuitry is positioned within the first DC-side cavity and between the first lower pocket and the first upper pocket;
the first control circuitry is positioned within the first DC-side cavity and between the first lower ridge and the first upper ridge;
the second DC-side subcell comprises second switch circuitry and second control circuitry;
the second switch circuitry is positioned within the second DC-side cavity and between the second lower pocket and the second upper pocket; and
the second control circuitry is positioned within the second DC-side cavity and between the second lower ridge and the second upper ridge.

8. The FPPA housing of claim 2, further comprising:
a second AC cavity, the magnetic core cavity being between the AC cavity and the second AC cavity.

9. (canceled)

10. The FPPA housing of claim 2, wherein the magnetic core cavity comprises:
a first DC-side core leg cavity positioned adjacent to the first DC-side cavity, a second DC-side core leg cavity positioned adjacent to the second DC-side cavity, and an AC-side core leg cavity positioned adjacent to the AC-side cavity; and
a first yoke cavity interconnecting the first and second DC-side cavities and the AC-side cavity, and a second yoke cavity positioned oppositely of the first yoke cavity and interconnecting the first and second DC-side cavities and the AC-side cavity.

11. The FPPA housing of claim 10, further comprising a magnetic core positioned within the magnetic core cavity, the magnetic core comprising:
a first DC-side core leg positioned in the first DC-side core leg cavity, a second DC-side core leg positioned in the second DC-side core leg cavity, and an AC-side core leg positioned in the AC-side core leg cavity; and
a first yoke positioned in the first yoke cavity, and a second yoke positioned in the second yoke cavity.

12. The FPPA housing of claim 11, wherein:
the first yoke comprises a first magnetic portion connecting the first DC-side core leg and the AC-side core leg and a second magnetic portion connecting the second DC-side core leg and the AC-side core leg; and
the second yoke comprises a first magnetic portion connecting the first DC-side core leg and the AC-side core leg and a second magnetic portion connecting the second DC-side core leg and the AC-side core leg.

13. The FPPA housing of claim 12, wherein:
each of the first magnetic portion and the second magnetic portion of the first yoke and the second yoke comprises an insulated magnetic energy coupler (IMEC), the IMEC comprising a plurality of distributed gaps with each gap comprising polyimide layer.

14. The FPPA housing of claim 2, wherein:
the first housing shell layer further comprises a first outer shell layer, the first outer shell layer comprising:
a first end and an opposite second end, the first upper DC-side cavity, the second upper DC-side cavity, and the upper AC-side cavity being between the first end and the opposite second end;
a first upper embedded cooling channel extending from the first end to the opposite second end and over the first upper DC-side cavity;
a second upper embedded cooling channel extending from the first end to the opposite second end and over the second upper DC-side cavity; and
a third upper embedded cooling channel extending from the first end to the opposite second end and over the upper AC-side cavity.

15. The FPPA housing of claim 14, wherein:
the second housing shell layer further comprises a second outer shell layer, the second outer shell layer comprising:
a first end and an opposite second end, the first lower DC-side cavity, the second lower DC-side cavity, and the lower AC-side cavity being between the first end and the opposite second end;
a first lower embedded cooling channel extending from the first end to the opposite second end and under the first lower DC-side cavity;
a second lower embedded cooling channel extending from the first end to the opposite second end and under the second lower DC-side cavity; and
a third lower embedded cooling channel extending from the first end to the opposite second end and under the lower AC-side cavity.

16. The FPPA housing of claim 15, wherein when the first housing shell layer is positioned over the second housing shell layer:
the first upper embedded cooling channel and the first lower embedded cooling channel are symmetrically aligned with each other;
the second upper embedded cooling channel and the second lower embedded cooling channel are symmetrically aligned with each other; and
the third upper embedded cooling channel and the third lower embedded cooling channel are symmetrically aligned with each other.

17. (canceled)

18. A field programmable power array (FPPA) housing, comprising:
a ceramic housing, the ceramic housing comprising a first direct current (DC)-side cavity positioned at a first end of the ceramic housing, a second DC-side cavity positioned at a second and opposite end of the ceramic housing, an alternating current (AC)-side cavity positioned between the first DC-side cavity and the second DC-side cavity, and a magnetic core cavity positioned between the first DC-side cavity and the second DC-side cavity; and
a submodule comprising an FPPA cell, the FPPA cell comprising:
a magnetic core with a DC-side winding and an AC-side winding on the magnetic core;
a first DC-side subcell positioned within the first DC-side cavity and coupled between a DC port and the DC-side winding; and
an AC-side subcell positioned within the AC-side cavity and coupled between an AC port and the AC-side winding.

19. The FPPA housing of claim 18, wherein the magnetic core comprises:
a DC-side core leg and an AC-side core leg, the DC-side winding being on the DC-side core leg and the AC-side winding being on the AC-side core leg;
a first yoke interconnecting the DC-side core leg and the AC-side core leg, and a second yoke interconnecting the DC-side core leg and the AC-side core leg;
the first yoke comprises a first insulated magnetic energy coupler (IMEC), the first IMEC comprising a plurality of distributed gaps with each gap comprising polyimide; and
the second yoke comprises a second IMEC, the second IMEC comprising a plurality of distributed gaps with each gap comprising polyimide.

20. The FPPA housing of claim 19, further comprising dielectric material wrapped around the first IMEC and the second IMEC.

21. The FPPA housing of claim 19, wherein:
the magnetic core cavity further comprises a DC-side core leg cavity and an AC-side core leg cavity;
the DC-side core leg is positioned in the DC-side core leg cavity and within close proximity to the DC-side subcell; and
the AC-side core leg is positioned in the AC-side core leg cavity and within close proximity to the AC-side subcell.

22. The FPPA housing of claim 21, wherein the DC-side core leg is grounded to a local subcell voltage potential of the DC-side subcell by connection to a positive or a negative DC rail of the DC-side subcell.

23. The FPPA housing of claim 21, wherein the AC-side core leg is grounded to a local subcell voltage potential of the AC-side subcell by connection to an AC voltage terminal of the AC-side subcell.
